(19) United States
(12) Patent Application Publication
(10) Pub. No.: US 2020/0185337 A1
(43) Pub. Date: Jun. 11, 2020

(54) Buffer Defense Band (BDB) Outside the Seal Ring to Enhance Crack Stopping in IC's

(71) Applicant: Dialog Semiconductor (UK) Limited, London (GB)

(72) Inventors: Iva Krasteva, Swindon (GB); Yi-Yeu Lin, Hsinchu City (TW)

(21) Appl. No.: 16/214,966

(22) Filed: Dec. 10, 2018

(51) Int. Cl. H01L 23/00; H01L 23/31; H01L 21/66

(52) U.S. Cl. CPC H01L 23/562; H01L 23/564; H01L 24/03; H01L 22/34; H01L 23/3114

(57) ABSTRACT

A plurality of prime dies are fabricated on a wafer. A plurality of frame structures are fabricated in vertical scribe lines separating the prime dies from one another. A plurality of test structures are fabricated in horizontal scribe lines separating the prime dies from one another. A seal ring is fabricated surrounding each of the prime dies. A buffer defense band is provided on the outside of each seal ring and extending from the seal ring to all borders of each of the prime dies. The prime dies are diced on the vertical scribe lines and on the horizontal scribe lines wherein the buffer defense band improves the robustness of the IC packaging window to prevent any cracks, chipping, or delaminating originating from any horizontal or vertical scribe lines from propagating into any of the prime dies.

### (1) TECHNICAL FIELD

This disclosure is related to manufacturing integrated circuits (IC's) assuring a better packaging process window, and more particularly, to minimizing cracking and delaminating as a result of sawing die packages.

### (2) BACKGROUND

A seal ring structure is a necessary and important component for integrated circuit (IC) product reliability to protect a core circuit region (so called Prime Die) of integrated circuits from die sawing stress and/or moisture. The typical seal ring is defined from a foundry as a part of the Process Design Kit (PDK). The width of the seal ring depends on the technology and is correlated to the IC package. In general, the width is flexibly-sized, but is around 20 μm. This is split into two zones the Sealring Ring Area (SRA) and Assembly Isolation (Al), each about 10 μm. In addition, the Seal Ring Area itself consists of two rings: an outer ring which is a Crackstop Region (CSR) and an inner ring which is a Moisture Oxidation Barrier (MOB). The size and structure of the SRA is determined by the foundry that makes the wafer. The Assembly Isolation width depends on the capability of assembly houses.

A Crackstop Region (outer ring) and a Moisture Oxidation Barrier (inner ring) are built as continuous rings around the entire die area and are made up of contacts, vias, metal, and inter-metal dielectric layers. The Outer Ring defines the edge of the die and is situated directly next to the scribe line (SL). In the scribe line are placed frame structures (for process in-line foundry control—structures like Critical Dimensions (CD), Overlay, thickness (THK), and so on) and test line (for Wafer Acceptance Test (WAT)—Process Control Monitoring (PCM)/electrical parameters—to measure threshold voltage (Vt), Drain current at saturation (Idsat), Oxide breakdown voltage (Vbd), and so on).

The constant quest for improving device functionality, performance, and cost reduction leads to device miniaturization including reduction of the wafer scribe line width. Wafers are diced on the scribe lines. If scribe lines are narrowed, this suggests the scribe line structures will be closer to the seal ring. When wafers are diced through narrow scribe lines, several dicing defects can occur, such as peeling/delamination, die chipping, and cracking. Some of these defects cause reliability failures of the IC. These defects significantly affect and limit process margins in saw dicing process steps and violate specific customer requirements for certain metal to metal gap sizes. These defect issues are very critical for packages such as wafer level packaging (WLP) and wafer level chip scale packaging (WLCSP) since the final physical package size is virtually the same size as the designed die size plus the remains of the SL (Scribe Line).

Several U.S. Patents and Patent Applications discuss various ways to reduce cracking. These include U.S. Pat. No. 9,679,855 (Lee et al), U.S. Pat. No. 8,125,052 (Jeng et al), U.S. Pat. No. 9,938,141 (Bretthauer et al), and U.S. Pat. No. 10,056,312 (Tu et al) and U.S. Patent Applications 2012/0074519 (Yeo et al), 2012/0326146 (Hui et al), 2006/0055007 (Yao et al), and 2013/0316471 (Tsai et al). All of these methods are different from the present disclosure.

### SUMMARY

It is the primary objective of the present disclosure to minimize or eliminate chipping, cracking propagation, and delamination into the prime die as a result of sawing.

It is a further objective of the present disclosure to provide a buffer defense band outside of the seal ring but within the die area to enhance robustness of the IC package.

Yet another objective is to provide a buffer defense band outside of the seal ring but within the die area to enhance robustness of the IC package and to minimize or eliminate chipping and delamination on the prime die as a result of sawing.

In accordance with the objectives of the present disclosure, a robust IC packaging process window is achieved. A wafer comprises a plurality of prime dies on the wafer, a plurality of vertical scribe lines separating the prime dies from one another, a plurality of horizontal scribe lines separating the prime dies from one another, a seal ring surrounding each of the prime dies and a buffer defense band on the outside of each seal ring and extending from the seal ring to all borders of each of the prime dies.

Also in accordance with the objectives of the present disclosure, a method of forming integrated circuit packages is achieved. A plurality of prime dies are fabricated on a wafer. A plurality of frame structures are fabricated in vertical scribe lines separating the prime dies from one another. A plurality of test structures are fabricated in horizontal scribe lines separating the prime dies from one another. A seal ring is fabricated surrounding each of the prime dies. A buffer defense band is provided on the outside of each seal ring and extending from the seal ring to all borders of each of the prime dies. The prime dies are diced on the vertical scribe lines and on the horizontal scribe lines wherein the buffer defense band prevents any cracks, chipping, or delaminating originating from any horizontal or vertical scribe lines from propagating into any of the prime dies.

### BRIEF DESCRIPTION OF THE DRAWINGS

In the accompanying drawings forming a material part of this description, there is shown:

FIGS. 1A and 1B are top views of a section of a wafer of the prior art.

FIG. 2 is an enlarged top view of a portion of a prime die of the prior art.

FIGS. 3A and 3B are top views of a section of a wafer of the present disclosure.

FIG. 4 is an enlarged top view of a portion of a prime die of the present disclosure.

FIG. 5 is a cross-sectional representation of a portion of a die of the prior art.

FIG. 6 is a cross-sectional representation of a portion of a die of the present disclosure.

### DETAILED DESCRIPTION

A sawing process produces unintended stress that manifests itself into micro cracks, peeling or delamination of passivation layers, and micro chipping. The disruptive energy is concentrated at the sharp end of the crack or delamination or at the edge line of peeling. Since the dielectric has less resistance to advancing micro cracks or peeling and has less adhesion to the metal layer, some of the micro cracks propagate from the edge and along the dielectric-metal boundary toward the prime die area. If the crack progresses through the Crackstop Region and the Moisture Oxidation Barrier into the prime die, this could result in core die interconnection failure and the IC circuit functionality may fail.

Therefore most customers define a minimum distance between the metal of the seal ring and metals in the scribe lines or an allowed percent of peeling in the scribe line to the seal ring. After sawing, the physical edge of the chip is rough with many minor cracks and peelings. The usual acceptance rule requires the clear from damages gap to be at least 3 μm from the Seal Ring to the sawed physical edge of the chip.

One possible solution to the cracking or delaminating problem is a wider scribe line. Since sawing is performed in the middle of the scribe line, a wider scribe line will provide a larger distance between the sawed physical edge of the die and the Seal Ring, leading to a higher probability that micro peeling will not reach to the Seal Ring. A drawback of implementing a wider scribe line is that this would affect the gross die per wafer (GDPW) number and would require a redesign of test lines and frame structures. Further, the new scribe line design would have to be qualified and characterized in the foundry and on the product.

The present invention provides a different solution to the problem. A new Buffer Defense Band (BDB) is placed outside the standard seal ring as an extension, but still within the die; that is, an extra buffer silicon area. This will affect the die size, so it is recommended that the BDB be kept to between about 1 to 5 μm. The Buffer Defense Band provides the simplest way to resolve the problem and to meet process margins in the saw dicing process step. This solution also can satisfy any customer requirements for metal to metal or peeling gap with respect to the seal ring edge. BDB defines a buffer space where the disruptive energy, concentrated at the sharp end of the crack or delamination at the edge line of peeling, has room to fade away.

The BDB is still within the die area and will increase the die area by a negligible amount for bigger dies and by less than 1% for smaller dies, as shown in Table 1 below.

TABLE 1

| | X | Y | Die area | |
|---|---|---|---|---|
| Die | μm | μm | μm² | % increased area |
| small | 1000 | 1000 | 1,000,000 | |
| | 1005 | 1005 | 1,010,025 | 0.99 |
| big | 7500 | 7500 | 56,250,000 | |
| | 7505 | 7505 | 5,6325,025 | 0.13 |

While the BDB will affect the gross die per wafer (GDPW) number, this will also be less than a 1% loss in GDPW.

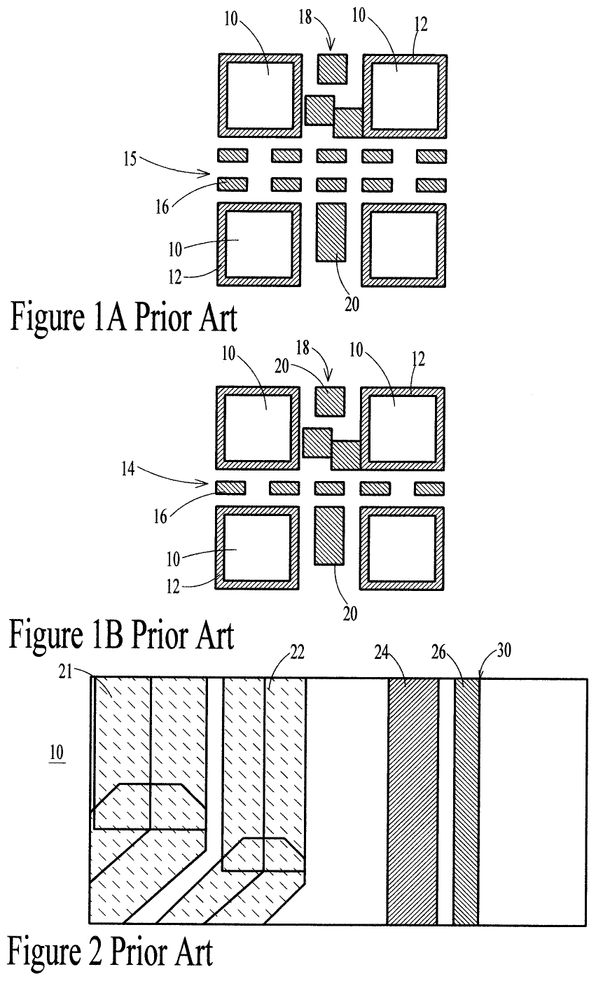

FIGS. 1A and 1B illustrate a conventional seal ring and die placement as shown in a top view. Prime dies 10 are shown surrounded by seal rings 12. FIG. 1A shows a double width X scribe line 15 while FIG. 1B shows a single width X scribe line 14. Test line structures 16 are shown in the X scribe lines. Y scribe lines 18 have frame structures 20 placed in them. FIG. 2 shows an enlargement of a portion of one prime die 10. Seal ring 12 is shown in this enlargement to consist of inner seal ring 24 displaced from the chip 21/22 and outer seal ring 26 ending at the edge 30 of the die.

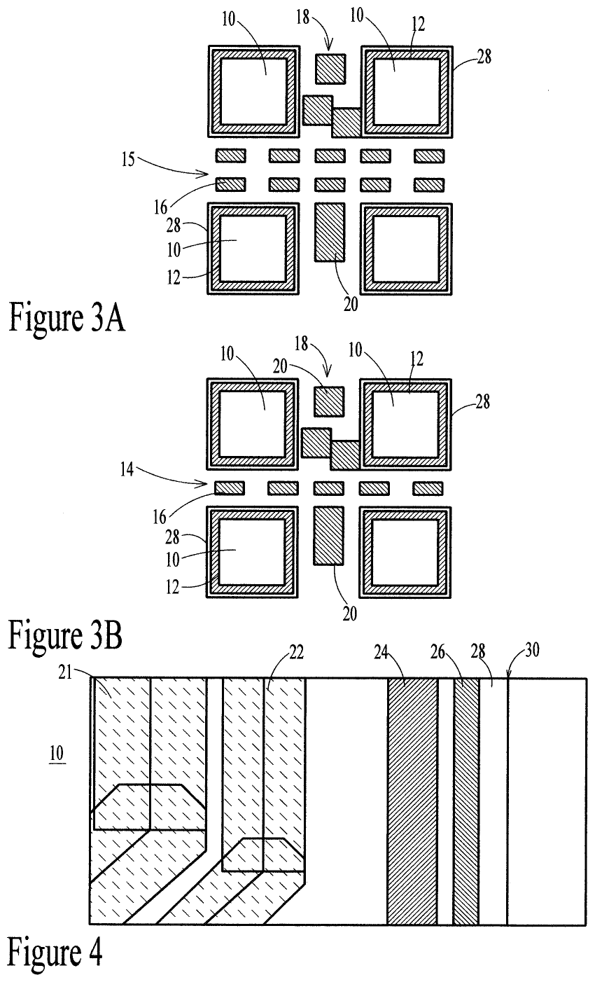

FIGS. 3A and 3B illustrate the seal ring and die placement of the present disclosure as shown in a top view. Prime dies 10 are shown surrounded by seal rings 12. FIG. 3A shows a double width X scribe line 15 while FIG. 3B shows a single width X scribe line 14. Test line structures 16 are shown in the X scribe lines. Y scribe lines 18 have frame structures 20 placed in them. Buffer Defense Band 28 is shown surrounding seal ring 12. FIG. 4 shows an enlargement of a portion of one prime die 10. Inner seal ring 24 is shown displaced from the chip 21/22. Between outer seal ring 26 and the edge 30 of the die 10 is the buffer defense band 28.

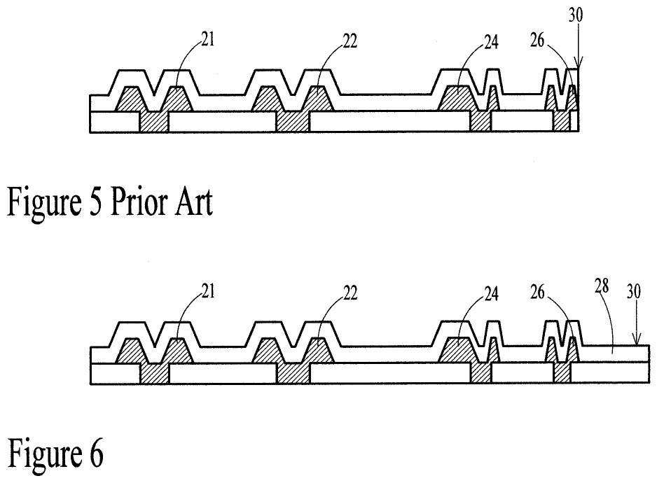

FIG. 5 illustrates a cross-sectional view of FIG. 2 and FIG. 6 illustrates a cross-sectional view of FIG. 4. Both figures show chip sections 21 and 22, inner seal ring 24, outer seal ring 26, and the die edge 30. FIG. 6 shows BDB 28.

The Buffer Defense Band outside the seal ring but still within the die area will enhance the robustness of the WLCSP IC's especially in applications such as mobile phones, wearable devices, tablets and note books, readers, and Internet of Things (IoT) that are exposed to additional mechanical stress during their life times.

The Buffer Defense Band can be applied to any IC with WLCSP to improve the robustness of the seal ring or to satisfy customer requirements. The BDB is not limited to WLCSP packages, but can be applied to any other type of package as well. Additional advantages of the BDB of the present disclosure are:
1. The Buffer Defense Band will enhance the crack stopping ring and will decrease sawing stress.
2. The BDB is part of the X and Y die dimensions and can be any size<10 μm, but preferably between 1-5 μm.
3. The BDB will satisfy customer requirements for the gap between the outer seal ring and any metal in the scribe line.
4. In the cases where double or triple the minimum scribe line width is used, the BDB will keep the physical die size smaller.

Although the preferred embodiment of the present disclosure has been illustrated, and that form has been described in detail, it will be readily understood by those skilled in the art that various modifications may be made therein without departing from the spirit of the disclosure or from the scope of the appended claims.

What is claimed is:

1. A wafer comprising:
a plurality of prime dies on said wafer, each prime die comprising:
a core circuit region;
a seal ring surrounding said core circuit region; and
a buffer defense band on the outside of each said seal ring and extending from said seal ring to all borders of said prime die;
a plurality of vertical scribe lines separating said prime dies from one another; and
a plurality of horizontal scribe lines separating said prime dies from one another.

2. The wafer according to claim 1 further comprising a plurality of frame structures in said vertical scribe lines and a plurality of test structures in said horizontal scribe lines.

3. The wafer according to claim 1 wherein said seal ring comprises an inner Moisture Oxidation Barrier and an outer Crackstop Region.

4. The wafer according to claim 1 wherein said buffer defense band comprises silicon and wherein said buffer defense band is between about 1 and 5 μm from said seal ring to each of said borders.

5. A method of forming integrated circuit packages comprising:
fabricating a plurality of prime dies on a wafer, fabricating each prime die comprising:
fabricating a core circuit area of said prime die;
fabricating a seal ring surrounding said core circuit area; and
providing a buffer defense band on the outside of said seal ring and extending from said seal ring to all borders of said prime die;
forming a plurality of frame structures in vertical scribe lines separating said prime dies from one another;
forming a plurality of test structures in horizontal scribe lines separating said prime dies from one another; and
dicing said prime dies on said vertical scribe lines and on said horizontal scribe lines wherein said buffer defense band prevents any cracks, chipping, or delaminating originating from any horizontal or vertical scribe lines from propagating into any of said prime dies.

6. The method according to claim 5 wherein said seal ring comprises an inner Moisture Oxidation Barrier and an outer Crackstop Region.

7. The method according to claim 5 wherein said buffer defense band comprises silicon and wherein said buffer defense band is between about 1 and 5 μm from said seal ring to each of said borders.

8. A method of forming integrated circuit packages comprising:
fabricating a plurality of prime dies on a wafer, fabricating each prime die comprising:
fabricating a core circuit area of said prime die;
fabricating a seal ring surrounding said core circuit area wherein said seal ring comprises an inner Moisture Oxidation Barrier and an outer Crackstop Region; and
providing a buffer defense band on the outside of said seal ring and extending from said seal ring to all borders of said prime die;
forming a plurality of frame structures in vertical scribe lines separating said prime dies from one another;
forming a plurality of test structures in horizontal scribe lines separating said prime dies from one another; and
dicing said prime dies on said vertical scribe lines and on said horizontal scribe lines wherein said silicon buffer defense band prevents any cracks, chipping, or delaminating originating from any horizontal or vertical scribe lines from propagating into any of said prime dies.

9. The method according to claim 8 wherein said buffer defense band is between about 1 and 5 μm from said seal ring to each of said borders.
